(19) United States
(12) Patent Application Publication
(10) Pub. No.: US 2015/0262819 A1
(43) Pub. Date: Sep. 17, 2015

(54) SEMICONDUCTOR DEVICE AND METHOD FOR MANUFACTURING THE SAME

(71) Applicant: Kabushiki Kaisha Toshiba, Tokyo (JP)

(72) Inventor: Takako Motai, Yokohama Kanagawa (JP)

(21) Appl. No.: 14/476,454

(22) Filed: Sep. 3, 2014

(30) Foreign Application Priority Data
Mar. 14, 2014 (JP) 2014-052674

(51) Int. Cl. H01L 21/02; H01L 29/205; H01L 29/778; H01L 29/78; H01L 29/66

(52) U.S. Cl. CPC H01L 21/02664; H01L 29/7842; H01L 29/66431; H01L 29/7786; H01L 29/205

(57) ABSTRACT

According to one embodiment, a semiconductor device includes a first semiconductor layer, a first electrode provided on the first semiconductor layer, and a second electrode provided on the first semiconductor layer. The second electrode is apart from the first electrode in a second direction crossing a first direction from the first semiconductor layer toward the first electrode. The first electrode includes a first electrode layer and a second electrode layer. The first electrode layer includes a first metal. The second electrode layer is provided between the first electrode layer and the first semiconductor layer, and includes a second metal. The second metal has a melting point lower than a melting point of the first metal. A distance along the second direction between the first electrode layer and the second electrode is shorter than a distance along the second direction between the second electrode layer and the second electrode.

### CROSS-REFERENCE TO RELATED APPLICATIONS

This application is based upon and claims the benefit of priority from the Japanese Patent Application No. 2014-052674, filed on Mar. 14, 2014; the entire contents of which are incorporated herein by reference.

### FIELD

Embodiments described herein relate generally to a semiconductor device and a method for manufacturing the same.

### BACKGROUND

For example, in a semiconductor device which uses a compound semiconductor having a broad band gap, a metal is stacked on a semiconductor layer and subjected to thermal treatment at a high temperature, so that the semiconductor layer and electrodes come in contact with each other. In such a semiconductor device, it is desired to raise a breakdown voltage between the electrodes.

### BRIEF DESCRIPTION OF THE DRAWINGS

FIG. 1 is a schematic cross-sectional view illustrating a semiconductor device according to a first embodiment;

FIGS. 2A to 2H are schematic cross-sectional views illustrating a manufacturing process of the semiconductor device according to the first embodiment;

FIG. 3 is a schematic cross-sectional view illustrating a semiconductor device according to a second embodiment; and

FIGS. 4A to 4F are schematic cross-sectional views illustrating a manufacturing process of the semiconductor device according to the second embodiment.

### DETAILED DESCRIPTION

According to one embodiment, a semiconductor device includes a first semiconductor layer, a first electrode, and a second electrode. The first electrode is provided on the first semiconductor layer. The first electrode is provided on the first semiconductor layer. The second electrode is provided on the first semiconductor layer. The second electrode is apart from the first electrode in a second direction. The second direction crosses a first direction from the first semiconductor layer toward the first electrode. The first electrode includes a first electrode layer and a second electrode layer. The first electrode layer includes a first metal. The second electrode layer is provided between the first electrode layer and the first semiconductor layer. The second electrode layer includes a second metal. The second metal has a melting point lower than a melting point of the first metal. A first distance along the second direction between the first electrode layer and the second electrode is shorter than a distance along the second direction between the second electrode layer and the second electrode.

According to one embodiment, a method for manufacturing a semiconductor device is disclosed. The semiconductor device includes a first semiconductor layer, a first electrode, and a second electrode. The first electrode is provided on the first semiconductor layer. The first electrode is provided on the first semiconductor layer. The second electrode is provided on the first semiconductor layer. The second electrode is apart from the first electrode in a second direction. The second direction crosses a first direction from the first semiconductor layer toward the first electrode. The first electrode includes a first electrode layer and a second electrode layer. The first electrode layer includes a first metal. The second electrode layer is provided between the first electrode layer and the first semiconductor layer. The second electrode layer includes a second metal. The second metal has a melting point lower than a melting point of the first metal. A first distance along the second direction between the first electrode layer and the second electrode is shorter than a distance along the second direction between the second electrode layer and the second electrode. The second electrode layer includes an facing surface, an upper surface and a side surface. The facing surface faces the first semiconductor layer. The upper surface is on a side opposite to the facing surface. The side surface crosses a plane perpendicular to the first direction. The method includes forming a first electrode layer to cover at least a part of the side surface and the upper surface and performing a thermal treatment to cause a temperature of the first semiconductor layer, the first electrode layer and the second electrode layer to be 600° C. or more.

Various embodiments will be described hereinafter with reference to the accompanying drawings.

In addition, the drawings are illustrated schematically or conceptually, and relations between thicknesses and widths of the respective portions and ratios of sizes between the portions may not be necessarily shown as actual dimensions. Further, even in a case where the same portions are shown, the dimensions or the ratios thereof may be shown differently from each other depending on the drawings.

In addition, in the specification and the drawings of the application, the same elements as those in a previously mentioned description relating to a previous drawing will be denoted with the same symbols and the detailed description thereof will appropriately not be made.

### First Embodiment

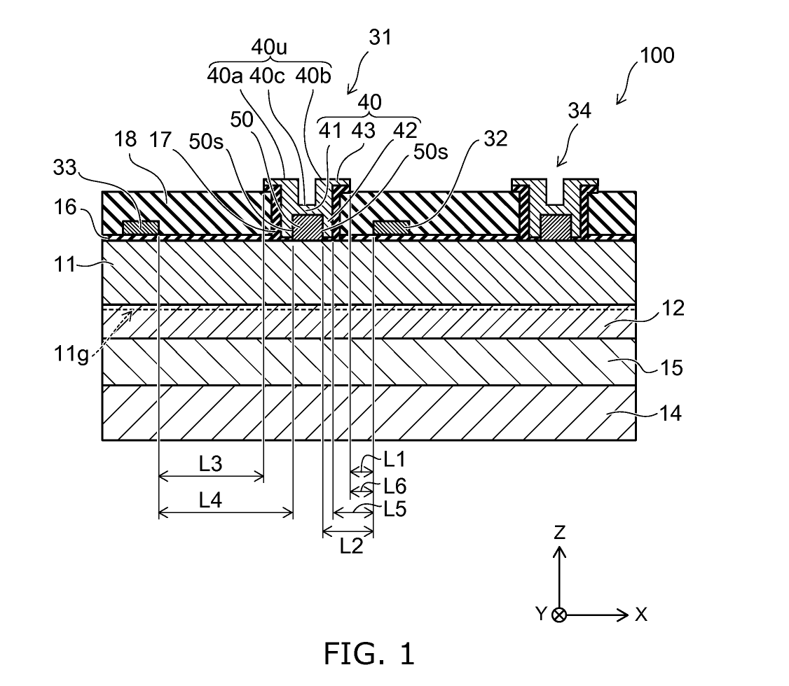

FIG. 1 is a schematic cross-sectional view illustrating a semiconductor device according to a first embodiment.

As illustrated in FIG. 1, a semiconductor device 100 according to the embodiment includes a first semiconductor layer 11, a first electrode 31 (a source electrode), and a second electrode 32 (a first gate electrode). In the example, the semiconductor device 100 further includes a second semiconductor layer 12, a substrate 14, a foundation layer 15, a gate insulating film 16, an insulating layer 18, a third electrode 33 (a second gate electrode), and a fourth electrode 34 (a drain electrode). The semiconductor device 100, for example, is a high electron mobility transistor (HEMT).

As the substrate 14, for example, a silicon substrate is used. The substrate 14, for example, may be a silicon carbide (SiC) substrate or a sapphire substrate. After a device is formed, the substrate 14, for example, may be removed by a back grinding method or a laser lift-off method.

The foundation layer 15 is provided on the substrate 14. The foundation layer 15, for example, includes a nitride semiconductor. The foundation layer 15, for example, contains AlₐGa₁₋ₐN (0≦a≦1). The foundation layer 15, for example, includes a plurality of nitride semiconductor layers. The foundation layer 15, for example, includes a plurality of AlN layers, a plurality of AlGaN layers, and a plurality of GaN layers. These layers, for example, are repeatedly stacked in order of the AlN layer, the AlGaN layer, and the GaN layer in a stacking direction of the substrate 14 and the foundation layer 15. In other words, the foundation layer 15, for example, is a superlattice layer. The foundation layer 15, for example, may be a stacked film which includes a plurality of AlGaN layers, each of which is changed in a composition ratio of Al between AlN and GaN in a stepped manner, but not limited thereto. The foundation layer 15, for example, may have one layer (a so-called inclined layer) of which the composition ratio of Al is continuously changed as it goes from AlN to GaN. In addition, the foundation layer 15 is provided as needed, and may not be provided.

The second semiconductor layer 12 is provided on the foundation layer 15. The second semiconductor layer 12, for example, includes a nitride semiconductor. The first semiconductor layer 11 is provided on the second semiconductor layer 12.

The first semiconductor layer 11, for example, contains Alₓ₁Ga₁₋ₓ₁N (0<x1<1). The second semiconductor layer 12, for example, contains Alₓ₂Ga₁₋ₓ₂N (0≦x2≦x1). The second semiconductor layer 12, for example, is a GaN layer. Further, the second semiconductor layer 12, for example, is not doped. The second semiconductor layer 12, for example, does not contain any impurity. A composition ratio of Al in the first semiconductor layer 11, for example, is higher than that in the second semiconductor layer 12. The first semiconductor layer 11, for example, is an AlGaN layer. For example, the second semiconductor layer 12 may be the AlGaN layer, and the first semiconductor layer 11 may be an AlGaN layer having a composition ratio of Al higher than that in the second semiconductor layer 12.

The second semiconductor layer 12, for example, is a channel layer, and the first semiconductor layer 11, for example, is a barrier layer. The first semiconductor layer 11 and the second semiconductor layer 12 form a heterojunction.

As described above, the composition of Al in the first semiconductor layer 11 is higher than the composition of Al in the second semiconductor layer 12. In other words, a lattice constant of the first semiconductor layer 11 is smaller than that of the second semiconductor layer 12. Thus, strain is caused in the first semiconductor layer 11, and piezoelectric polarization is generated in the first semiconductor layer 11 by a piezoelectric effect. Thereby, a two-dimensional electron gas 11g is formed in the second semiconductor layer 12 near a interface with the first semiconductor layer 11.

The gate insulating film 16 is provided on the first semiconductor layer 11. For the gate insulating film 16, for example, SiO₂, SiN, Al₂O₃, TiO₂, Ta₂O₅, HfO₂, ZrO₂, or the like is used. The gate insulating film 16 is provided as needed, and may not be provided.

The first electrode 31 is provided on the first semiconductor layer 11. The first electrode 31, for example, is in contact with the first semiconductor layer 11. The first electrode 31, for example, comes into ohmic contact with the first semiconductor layer 11.

A direction from the first semiconductor layer 11 toward the first electrode 31 will be assumed as a Z-axis direction (a first direction). A direction perpendicular to the Z-axis direction will be assumed as an X-axis direction. A direction perpendicular to the Z-axis direction and perpendicular to the X-axis direction will be assumed as a Y-axis direction. In the example, the X-axis direction is a direction (a second direction) from the first electrode 31 toward the second electrode 32.

The second electrode 32 is provided on the first semiconductor layer 11. The second electrode 32 is apart from the first electrode 31. Further, in the example, the second electrode 32 is provided on the gate insulating film 16. For the second electrode 32, for example, a stacked structure of nickel (Ni) and gold (Au) is used.

The third electrode 33 is provided on the first semiconductor layer 11. The third electrode 33 is apart from the first electrode 31 and the second electrode 32. The first electrode 31 is provided between the second electrode 32 and the third electrode 33. The third electrode 33 can be applied with the same configuration and the same material as those of the second electrode 32.

The fourth electrode 34 is provided on the first semiconductor layer 11. The fourth electrode 34 is apart from the first to third electrodes 31 to 33. The second electrode 32 is provided between the first electrode 31 and the fourth electrode 34. The fourth electrode 34, for example, comes into ohmic contact with the first semiconductor layer 11. The fourth electrode 34 can be applied with the same configuration and the same material as the first electrode 31.

In the semiconductor device 100, for example, the concentration of the two-dimensional electron gas 11g under the second electrode 32 is increased or decreased by controlling a voltage applied to the second electrode 32 (the gate electrode). Thereby, an electric current flowing between the first electrode 31 and the fourth electrode 34 is controlled.

The insulating layer 18 is provided on the gate insulating film 16. The insulating layer 18, for example, is formed to fill portions other than the first to fourth electrodes 31 to 34 on the gate insulating film 16. In the insulating layer 18, for example, a silicon oxide (SiO₂) or a silicon nitride (SiN) can be used.

The first electrode 31 includes a first electrode layer 40 and a second electrode layer 50. The second electrode layer 50 is provided between the first electrode layer and the first semiconductor layer 11. For example, the second electrode layer 50 is in contact with the first semiconductor layer 11.

The first electrode layer 40 includes a first metal. The melting point of the first metal is relatively high. The first metal, for example, contains at least one of tungsten (W), molybdenum (Mo) and tantalum (Ta).

The second electrode layer 50 includes a second metal. The melting point of the first metal is higher than that of the second metal. The second metal, for example, includes at least one of aluminum (Al), titanium (Ti), gold (Au) and nickel (Ni).

As the second electrode layer 50, for example, a stacked structure of metals is used. For example, a configuration of stacking Al on Ti is used. A stacked structure of Au and Ni may be used.

The first semiconductor layer 11 can be formed to come into good (for example, ohmic) electrical contact with an electrode through thermal treatment as to be described below.

A first distance L1 in the X-axis direction between the first electrode layer 40 and the second electrode 32 is shorter than a second distance L2 in the X-axis direction between the second electrode layer 50 and the second electrode 32.

A third distance L3 along the X-axis direction between the first electrode layer 40 and the third electrode 33 is shorter than a fourth distance L4 in the X-axis direction between the second electrode layer 50 and the third electrode 33.

In the semiconductor device 100 according to the embodiment, a distance between the first electrode 31 (the source electrode) and the second electrode 32 (the gate electrode) is the first distance L1. In other words, an inter-electrode distance is set depending on a distance between the gate electrode and the first electrode layer 40 which includes a metal having a high melting point. In this way, for example, the first electrode layer 40 is disposed such that the inter-electrode distance is determined depending on a position of a layer including the metal having a high melting point. Thereby, it is possible to increase a breakdown voltage between the electrodes (for example, between the source electrode and the gate electrode).

For example, in a compound semiconductor device having a broad band gap, it may be difficult to form the ohmic contact between a semiconductor layer (for example, the first semiconductor layer 11) and an electrode. For example, it may be difficult to form the ohmic contact only by doping the semiconductor layer at a high concentration and by stacking a metal thereon. A metal is stacked on the semiconductor layer and then the semiconductor layer and stacked metal are subjected to thermal treatment. Thereby, for example, it is possible to form a good electrical contact.

For example, in the first semiconductor layer 11, a compound semiconductor using an n-type GaN layer or a non-doped GaN layer is used. In this case, as a metal for forming an electrical contact, a metal containing Al is used, and then subjected to the thermal treatment at a temperature of 600° C. or more. Thereby, for example, it is possible to form a good electrical contact. On the other hand, the melting point of Al is about 660° C. For this reason, Al may be melted to degrade morphology of a metal surface in the thermal treatment at a high temperature. For example, in the thermal treatment, Al is fluidized and the shape of a metal layer including Al is deformed compared to that before the thermal treatment is performed. Thereby, it is difficult to control the inter-electrode distance and the shape of the electrode.

For example, a distance between the source electrode (the first electrode 31) and the gate electrode (the second electrode 32) is designed to be about 1.5 μm. Before the thermal treatment is performed, the metal layer containing Al used for the electrode, for example, is processed such that a distance from the gate electrode becomes 1.5 p.m. The thermal treatment is performed on the constitution recited above at a high temperature, so that the metal layer containing Al is melted and the width of the metal layer is changed. For example, a distance between the source electrode and the gate electrode may be changed up to about 1.0 μm. Thereby, for example, a breakdown voltage between the source electrode and the gate electrode may be degraded.

On the contrary, in the embodiment, a distance between the source electrode (the first electrode 31) and the gate electrode (the second electrode 32) is determined depending on a position of the first electrode layer 40 which includes a metal having a high melting point. For example, the melting point of W is about 3,422° C. Even when the thermal treatment is performed at a high temperature in order to form a good electrical contact, the width of the first electrode layer 40 (the length in the X-axis direction) is difficult to be changed. Thereby, a distance between the source electrode (the first electrode 31) and the gate electrode (the second electrode 32) is easily controlled. For example, the inter-electrode distance can be maintained as it is designed. It is possible to improve the breakdown voltage between the electrodes.

The first electrode layer 40, for example, includes a first portion 41, a second portion 42, and a third portion 43.

The first portion 41 is provided on the second electrode layer 50.

The second portion 42 is arranged with the second electrode layer 50 in a direction crossing the Z-axis direction, and is in contact with the second electrode layer 50. At least a part of the second portion 42 is arranged with the second electrode layer 50 in the X-axis direction.

At least a part of the third portion 43 is provided on the second portion 42, and is arranged with the first portion 41 in the X-axis direction.

As illustrated in FIG. 1, a distance L5 in the X-axis direction between the second portion 42 and the second electrode 32 is longer than a distance L6 along the X-axis direction between the third portion 43 and the second electrode 32.

A distance between the third portion 43 and the second electrode layer 50 is longer than a distance between the second portion 42 and the second electrode layer 50. Depending on such a position of the third portion 43, a distance between the first electrode 31 and the second electrode 32 is determined. Thereby, for example, it is possible to more easily control the inter-electrode distance.

The second electrode layer 50 has a side surface 50s crossing a plane perpendicular to the Z-axis direction. The first electrode layer 40, for example, is provided to cover at least a part of the side surface 50s.

In a case where a metal containing Al is used as a metal for forming an electrical contact, the metal is subjected to the thermal treatment at a high temperature to melt Al as described above. Furthermore, Al may be spluttered to a surrounding area of the first electrode 31. For example, Al is attached to an insulating film which is provided between the source electrode and the gate electrode. When Al reacts with the insulating film made of a silicon oxide or a silicon nitride, insulation failure or the like may be caused. Further, for example, the characteristics of the device are changed when Al is attached to the surrounding area of the gate electrode or the gate insulating film.

On the contrary, in the semiconductor device 100 according to the embodiment, the first electrode layer 40 which includes a metal having a high melting point is provided to cover the side surface 50s and an upper surface of the second electrode layer 50 which includes a metal having a low melting point. Thereby, in the thermal treatment at a high temperature, it is possible to suppress the spluttering of the metal such as Al. The degradation (decrease) of the breakdown voltage between the electrodes can be suppressed. In other words, a high breakdown voltage is obtained.

The first electrode layer 40 has a lower surface (a first surface) facing the second electrode layer 50. The first electrode layer 40 has an upper surface 40u (a second surface). The upper surface 40u is on a side opposite to the lower surface. In the example, the upper surface 40u includes a first region 40a, a second region 40b, and a third region 40c. The third region 40c is provided between the first region 40a and the second region 40b. A distance between the third region 40c and the first semiconductor layer 11 is shorter than a distance between the first region 40a and the first semiconductor layer 11. The distance between the third region 40c and the first semiconductor layer 11 is shorter than a distance between the second region 40b and the first semiconductor layer 11.

An insulating layer 17 is provided between the first electrode 31 and the insulating layer 18. For the insulating layer 17, for example, a silicon nitride is used. In the example, the insulating layer 17 is provided also between a part of the first electrode layer 40 and the first semiconductor layer 11. The insulating layer 17 is not provided between the second electrode layer 50 and the first semiconductor layer 11.

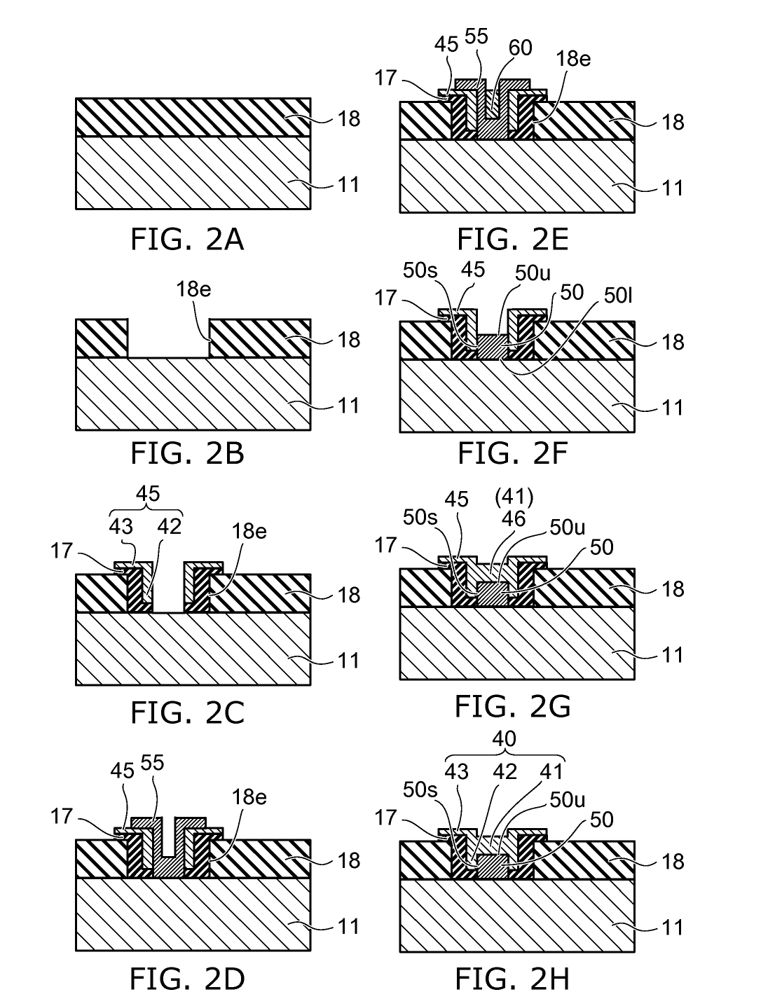

FIGS. 2A to 2H are schematic cross-sectional views illustrating a manufacturing process of the semiconductor device according to the first embodiment.

FIGS. 2A to 2H illustrates a manufacturing process of the first electrode 31 in the manufacturing process of the semiconductor device 100.

The foundation layer 15 (for example, an AlGaN layer) and the second semiconductor layer 12 (for example, an AlGaN layer) are epitaxially-grown on the substrate 14. The first semiconductor layer 11 (for example, a non-doped AlGaN layer) is formed on the surface. In FIGS. 2A to 2H, the substrate 14, the foundation layer 15, and the second semiconductor layer 12 are not illustrated.

As illustrated in FIG. 2A, the insulating layer 18 is provided on the first semiconductor layer 11. As the insulating layer 18, for example, a silicon nitride (SiN) film is used. For the deposition, a plasma enhanced-chemical vapor deposition (PE-CVD) method may be employed. The thickness of the silicon nitride film (the length in the Z-axis direction), for example, is about 200 nm.

As illustrated in FIG. 2B, a part of the insulating layer 18 is etched off to form an opening 18e according to a region where the first electrode 31 is formed.

As illustrated in FIG. 2C, thereafter, the insulating layer 17 is formed. On the insulating layer 17, a first metal layer 45 which includes the first metal is formed. The first metal layer 45, for example, becomes a part of the first electrode layer 40 (the second portion 42 and the third portion 43). As the insulating layer 17, for example, a SiN film is used, and the thickness of the insulating layer 17 is about 50 nm. In the first metal layer 45, for example, tungsten is used, and the thickness of the first metal layer 45 is about 100 nm. With the insulating layer 17, for example, it is possible to suppress the direct contact of the first semiconductor layer 11 (the AlGaN layer) with the first metal layer 45 (tungsten). In the embodiment, it is preferable to provide the insulating layer 17, but it may not be provided.

A part of the first metal layer 45 which is provided in a portion covering the opening 18e is removed by etching the part using a resist mask. Then, a part of the insulating layer 17 is removed using the first metal layer 45 as a mask so as to make a part of the first semiconductor layer 11 to be exposed.

As illustrated in FIG. 2D, thereafter, a second metal layer 55 serving as the second electrode layer 50 is stacked. The second metal layer 55 includes the second metal. At least a part of the second metal layer 55 is arranged with the first metal layer 45 in the X-axis direction, and is in contact with the first metal layer 45.

For example, the second metal layer 55 is formed using a stacked structure of Ti/Al. An Al film having a thickness of about 200 nm is stacked on a Ti film having a thickness of about 20 nm. The second metal layer 55 covers the exposed surface of the first semiconductor layer 11. Then, the other portions in the second metal layer 55 except the portion covering the opening 18e are removed. In other words, for example, the second metal layer 55 is patterned such that the second metal layer 55 is left only in a region of the first metal layer 45 (tungsten layer).

As illustrated in FIG. 2E, a resist 60 and the like are coated over the entire surface and are subjected to ashing. Thereby, the resist 60 is removed while leaving a portion provided on a part of the second metal layer 55. For example, it is possible to protect only the portion corresponding to the opening 18e using the resist 60.

As illustrated in FIG. 2F, a part of the second metal layer 55 is etched off using the resist 60 as a mask. Thereby, the second electrode layer 50 is formed. Then, the resist 60 is removed.

The second electrode layer 50 has a lower surface 501 facing the first semiconductor layer 11 and an upper surface 50u on a side opposite to the lower surface 501. The side surface 50s of the second electrode layer 50 covers the first metal layer 45 and the insulating layer 17.

As illustrated in FIG. 2G, thereafter, a third metal layer 46 including the first metal is stacked on the second electrode layer 50. For example, the third metal layer 46 is formed using W, and the thickness of the third metal layer 46 is about 100 nm. For example, the third metal layer 46 becomes the first portion 41 of the first electrode layer 40. In this way, the first electrode layer 40 is formed.

Thereafter, for example, a thermal treatment process is performed in an inactive gas atmosphere. In the thermal treatment process, the first semiconductor layer 11, the first electrode layer 40, and the second electrode layer 50 are heated at a temperature of 600° C. or more. Thereby, as illustrated in FIG. 2H, a good (for example, ohmic) electrical contact can be formed between the first semiconductor layer 11 and the second electrode layer 50.

As described above, the first electrode layer 40 is formed to cover at least a part of the side surface 50s and the upper surface 50u of the second electrode layer 50. The side surface 50s covers at least any one of the first electrode layer 40 and the insulating layer 17. Then, the thermal treatment is performed.

In this way, when the thermal treatment is performed, the first electrode layer 40 which includes the first metal having a high melting point covers the side surface 50s of the second electrode layer 50 and the upper surface 50u of the second electrode layer 50. Thereby, even when the thermal treatment is performed at a high temperature, it is possible to suppress the collapse of the shape (pattern) of the first electrode 31. The inter-electrode distance can be easily controlled, and the degradation (decrease) of the breakdown voltage can be suppressed. Further, it is possible to suppress the spluttering of a metal such as Al in the thermal treatment. Thereby, it is possible to suppress the degradation (decrease) of the breakdown voltage.

### Second Embodiment

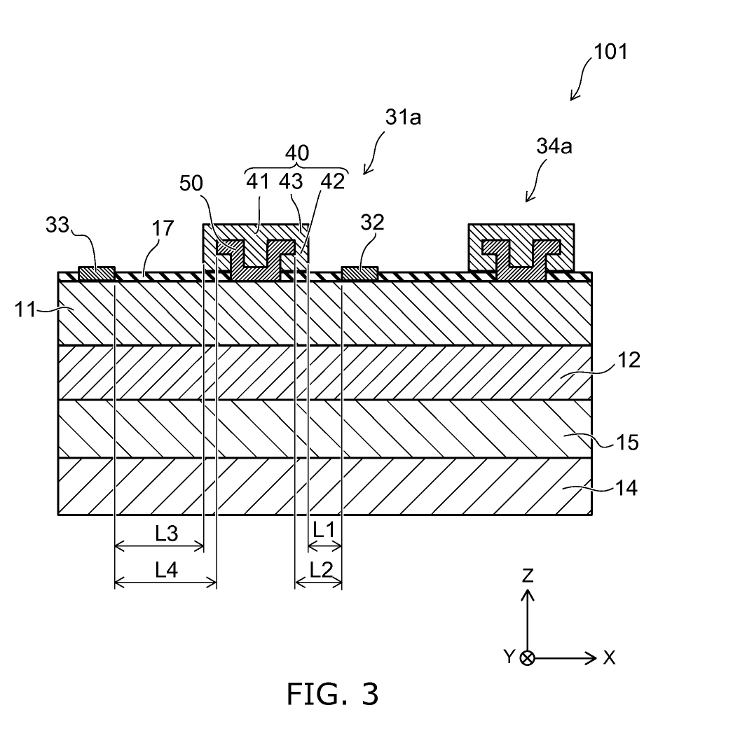

FIG. 3 is a schematic cross-sectional view illustrating a semiconductor device according to a second embodiment.

As illustrated in FIG. 3, a semiconductor device 101 according to the second embodiment is provided with the first semiconductor layer 11, a first electrode 31a, the second electrode 32, the substrate 14, the foundation layer 15, the third electrode 33, a fourth electrode 34a, and the like. In this regard, the same configurations as those described in the semiconductor device 100 can be applied. In the example, the insulating layer 17 is provided on a part of the first semiconductor layer 11, and between the first electrode layer 40 and the first semiconductor layer 11.

Even in the example, the first electrode 31a includes the first electrode layer 40 and the second electrode layer 50.

The first distance L1 in the X-axis direction between the first electrode layer 40 and the second electrode 32 is shorter than the second distance L2 in the X-axis direction between the second electrode layer 50 and the second electrode 32.

The third distance L3 in the X-axis direction between the first electrode layer 40 and the third electrode 33 is shorter than the fourth distance L4 in the X-axis direction between the second electrode layer 50 and the third electrode 33.

In the semiconductor device 101, an inter-electrode distance is determined depending on a distance between the first electrode layer 40 which includes a metal having a high melting point and the gate electrode. Thereby, it is possible to increase the breakdown voltage between the electrodes (for example, between the source electrode and the gate electrode).

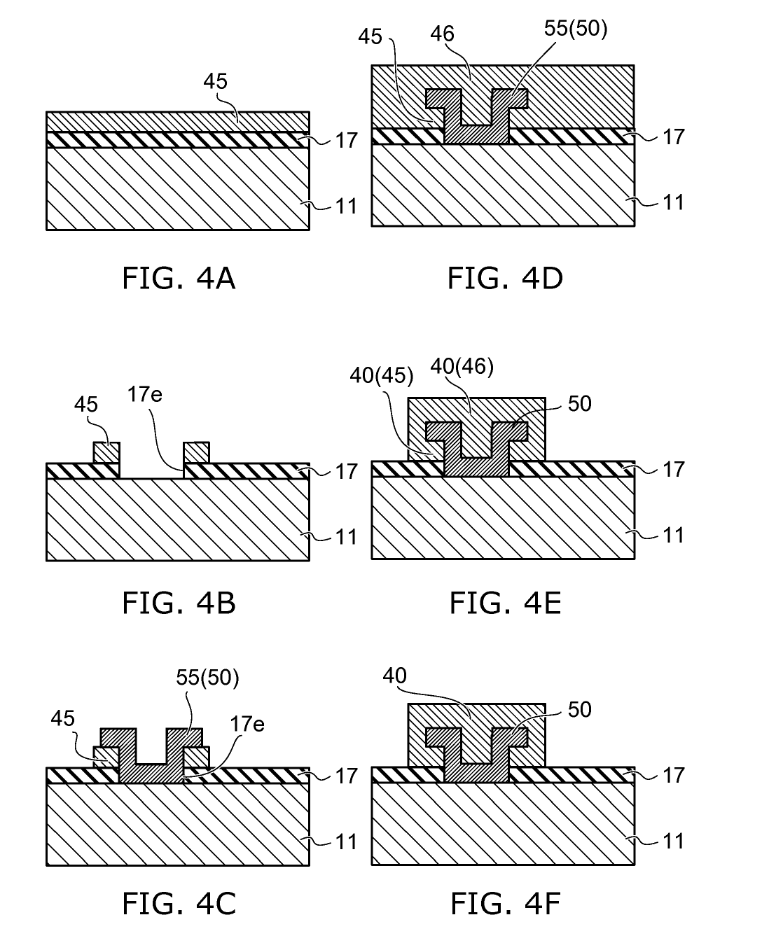

FIGS. 4A to 4F are schematic cross-sectional views illustrating a manufacturing process of the semiconductor device according to the second embodiment.

FIGS. 4A to 4F illustrate a manufacturing process of the first electrode 31a in the manufacturing process of the semiconductor device 101.

As illustrated in FIG. 4A, the insulating layer 17 is formed on the first semiconductor layer 11. For example, as the insulating layer 17, for example, a SiN film is used, and the thickness of the insulating layer 17 is about 20 nm. On the insulating layer 17, the first metal layer 45 which includes the first metal is formed. For example, a part of the first metal layer 45 becomes a part (the second portion 42) of the first electrode layer 40. In the first metal layer 45, for example, tungsten is used, and the thickness of the first metal layer 45 is about 100 nm.

As illustrated in FIG. 4B, a part of the first metal layer 45 is etched and removed while leaving a surrounding area of the region where the second electrode layer 50 is formed. Furthermore, the insulating layer 17 provided on the region where the second electrode layer 50 is formed is etched off to form an opening 17e. Thereby, a part of the first semiconductor layer 11 is exposed.

Thereafter, the second metal layer 55 which becomes the second electrode layer 50 is stacked over the entire surface. For example, the second metal layer 55 is formed using a stacked structure of Ti/Al. For example, an Al film having a thickness of about 200 nm is stacked on a Ti film having a thickness of about 20 nm. The second metal layer 55 is etched off according to a pattern of the second electrode layer 50 to be formed. Thereby, the second electrode layer 50 is formed.

As illustrated in FIG. 4C, in the opening 17e, the second electrode layer 50 is provided on the first semiconductor layer 11 and is in contact with the first semiconductor layer 11. The second electrode layer 50 is also provided on a part of the first metal layer 45. In this way, for example, an ohmic contact pattern is formed in the region where tungsten is left.

As illustrated in FIG. 4D, thereafter, the third metal layer 46 which includes the first metal is deposited. For example, in the third metal layer 46, tungsten is used, and the thickness of the third metal layer 46 is about 300 nm. A part of the third metal layer 46, for example, becomes the first portion 41 of the first electrode layer 40.

As illustrated in FIG. 4E, the third metal layer 46 is etched off according to a pattern of the first electrode 31a to be formed, and the first electrode layer 40 is formed. For example, tungsten is left only in the peripheral portion of the ohmic contact pattern (the second electrode layer 50) so as to fill the ohmic contact pattern.

As illustrated in FIG. 4F, for example, the thermal treatment is performed at a temperature of 600° C. or more in an inactive gas atmosphere. Thereby, it is possible to form a good electrical contact between the first semiconductor layer 11 and the second electrode layer 50.

In this way, even in the second embodiment, when the thermal treatment is performed, the first electrode layer 40 which includes the first metal having a high melting point covers the side surface of the second electrode layer 50 and the upper surface of the second electrode layer 50. Thereby, it is possible to suppress the degradation (decrease) of the breakdown voltage.

According to the embodiment, it is possible to provide the semiconductor device having a high breakdown voltage.

In the specification of the application, “perpendicular” refer to not only strictly perpendicular but also include, for example, the fluctuation due to manufacturing processes, etc. It is sufficient to be substantially perpendicular.

Hitherto, the embodiments of the invention have been described with reference to the specific examples. However, the embodiments of the invention are not limited to these specific examples. For example, a person skilled in the art can similarly implement the invention by selecting the specific configurations of the respective elements such as the first semiconductor layer, the second semiconductor layer, the first to fourth electrodes, the first electrode layer, the second electrode layer, the insulating layer, and the first to third metal layers from among a known scope. As long as the similar advantages can be obtained, it will be considered as falling within the scope of the invention.

Further, any two or more components of the specific examples may be combined within the extent of technical feasibility and are included in the scope of the invention to the extent that the purport of the invention is included.

Moreover, all semiconductor devices and methods for manufacturing the same practicable by an appropriate design modification by one skilled in the art based on the semiconductor devices and the methods for manufacturing the same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor layer;
a first electrode provided on the first semiconductor layer; and
a second electrode provided on the first semiconductor layer, the second electrode being apart from the first electrode in a second direction, the second direction crossing a first direction from the first semiconductor layer toward the first electrode,
the first electrode including
a first electrode layer including a first metal, and
a second electrode layer provided between the first electrode layer and the first semiconductor layer, the second electrode layer including a second metal, the second metal having a melting point lower than a melting point of the first metal,
a first distance along the second direction between the first electrode layer and the second electrode being shorter than a distance along the second direction between the second electrode layer and the second electrode.

2. The device according to claim 1, further comprising
a third electrode provided on the first semiconductor layer,
the first electrode being provided between the second electrode and the third electrode,
a distance in the second direction between the first electrode layer and the third electrode being shorter than a distance along the second direction between the second electrode layer and the third electrode.

3. The device according to claim 1, wherein the first electrode layer includes
a first portion provided on the second electrode layer, and
a second portion arranged with the second electrode layer in a direction crossing the first direction, the second portion being in contact with the second electrode layer.

4. The device according to claim 1, wherein
the second electrode layer has a side surface crossing a plane perpendicular to the first direction, and
the first electrode layer covers at least a part of the side surface.

5. The device according to claim 3, wherein
the first electrode layer further includes a third portion,
at least a part of the second portion is arranged with the second electrode layer in the second direction,
at least a part of the third portion is provided on the second portion, the at least the part of the third portion is arranged with the first portion in the second direction, and
a distance in the second direction between the second portion and the second electrode is longer than a distance along second direction between the third portion and the second electrode.

6. The device according to claim 1, further comprising
an insulating layer provided between a part of the first electrode layer and the first semiconductor layer.

7. The device according to claim 1, wherein
the first electrode layer has a first surface and a second surface, the first electrode faces the second electrode, the second surface is on a side opposite to the first surface,
the second surface includes a first region, a second region and a third region, the third region being provided between the first region and the second region, and
a distance between the third region and the first semiconductor layer is shorter than a distance between the first region and the first semiconductor layer, and is shorter than a distance between the second region and the first semiconductor layer.

8. The device according to claim 1, further comprising:
a fourth electrode; and
a second semiconductor layer,
the fourth electrode being provided on a first semiconductor layer,
the second electrode being provided between the first electrode and the fourth electrode,
the first semiconductor layer being provided on the second semiconductor layer.

9. The device according to claim 8, wherein the second semiconductor layer forms a heterojunction with the first semiconductor layer.

10. The device according to claim 8, wherein
the first semiconductor layer includes Alₓ₁Ga₁₋ₓ₁N (0<x1<1), and
the second semiconductor layer includes Alₓ₂Ga₁₋ₓ₂N (0≦x2<x1).

11. The device according to claim 1, wherein the first metal includes at least one of tungsten, molybdenum and tantalum.

12. The device according to claim 1, wherein the second metal includes at least one of aluminum, titanium, gold and nickel.

13. A method for manufacturing a semiconductor device, the semiconductor device including a first semiconductor layer, a first electrode provided on the first semiconductor layer, and a second electrode provided on the first semiconductor layer, the second electrode being apart from the first electrode in a second direction, the second direction crossing a first direction from the first semiconductor layer toward the first electrode, the first electrode including a first electrode layer and a second electrode layer, the first electrode layer including a first metal, the second electrode layer being provided between the first electrode layer and the first semiconductor layer, the second electrode layer including a second metal, the second metal having a melting point lower than a melting point of the first metal, a first distance along the second direction between the first electrode layer and the second electrode being shorter than a distance along the second direction between the second electrode layer and the second electrode, the second electrode layer including an facing surface, an upper surface and a side surface, the facing surface facing the first semiconductor layer, the upper surface being on a side opposite to the facing surface, the side surface crossing a plane perpendicular to the first direction, the method comprising:
forming the first electrode layer to cover at least a part of the side surface and the upper surface; and
performing a thermal treatment to cause a temperature of the first semiconductor layer, the first electrode layer and the second electrode layer to be 600° C. or more.

14. The method according to claim 13, wherein
the semiconductor device further includes an insulating layer provided between the first electrode layer and the first semiconductor layer, and
the performing of thermal treatment includes making the side surface to be covered at least one of the first electrode layer and the insulating layer.

15. The method according to claim 13, wherein the first metal includes at least one of tungsten, molybdenum and tantalum.

16. The method according to claim 13, wherein the second metal includes at least one of aluminum, titan, gold and nickel.

17. The method according to claim 13, wherein the first semiconductor layer includes Alₓ₁Ga₁₋ₓ₁N (0<x1<1).

18. The method according to claim 13, wherein the semiconductor device further includes a third electrode provided on the first semiconductor layer,
the first electrode is provided between the second electrode and the third electrode, and
a distance in the second direction between the first electrode layer and the third electrode is shorter than a distance along the second direction between the second electrode layer and the third electrode.

19. The method according to claim 13, wherein the semiconductor device further includes a second semiconductor layer provided under the first semiconductor layer, and the second semiconductor layer forms a heterojunction with the first semiconductor layer.

20. The method according to claim 19, wherein the second semiconductor layer includes Alₓ₂Ga₁₋ₓ₂N (0≦x2<x1).
